(19) United States
(12) Patent Application Publication
(10) Pub. No.: US 2025/0261538 A1
(43) Pub. Date: Aug. 14, 2025

(54) DISPLAY DEVICE

(71) Applicant: LG Display Co., Ltd., Seoul (KR)

(72) Inventor: Hokyung YU, Paju-si (KR)

(73) Assignee: LG Display Co., Ltd., Seoul (KR)

(21) Appl. No.: 18/886,071

(22) Filed: Sep. 16, 2024

(30) Foreign Application Priority Data
Feb. 8, 2024 (KR) 10-2024-0019691

(51) Int. Cl. H10K 59/80; H10K 59/65

(52) U.S. Cl. CPC H10K 59/871; H10K 59/65; H10K 59/8792

(57) ABSTRACT

A display device including a display panel including a display area, and an optical area disposed in the display area and including a through-hole, a cover member disposed on the display panel, a support member disposed below the display panel, a metal plate disposed below the support member, a frame including a lower frame disposed below the metal plate, and a lateral frame disposed to surround side surfaces of the display panel, the support member, and the metal plate, a molding member disposed between the display panel, the cover member, the support member, the metal plate, and the frame, and a conductive member disposed between the molding member and the side surface of the display panel, the support member, and the metal plate at one side of the display panel adjacent to the optical area.

### CROSS-REFERENCE TO RELATED APPLICATIONS

This application claims priority to Korean Patent Application No. 10-2024-0019691 filed on Feb. 8, 2024, in the Korean Intellectual Property Office, the disclosure of which is incorporated herein by reference.

### BACKGROUND

### Technical Field

The present specification relates to a display device, and more particularly, to a display device capable of reducing stress to be applied to a display panel.

### Description of the Related Art

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display (LCD) device, a field emission display (FED) device, an electrowetting display (EWD) device, an organic light-emitting display (OLED) device, and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### SUMMARY

An object to be achieved by an embodiment of the present specification is to provide a display device capable of reducing stress to be applied to a display panel.

An object to be achieved by another embodiment of the present specification is to provide a display device capable of minimizing the occurrence of cracks caused by thermal deformation in a high-temperature or low-temperature environment.

Objects of the present disclosure are not limited to the above-mentioned objects, and other objects, which are not mentioned above, can be clearly understood by those skilled in the art from the following descriptions.

To achieve these and other advantages and in accordance with objects of the disclosure, as embodied and broadly described herein, a display device includes a display panel including a display area, an optical area disposed in the display area and including a through-hole, and a non-display area configured to surround the display area, a cover member disposed on a top surface of the display panel, a support member disposed on a rear surface of the display panel, a metal plate disposed on a rear surface of the support member, a frame including a lower frame disposed on a rear surface of the metal plate, and a lateral frame disposed to surround side surfaces of the display panel, the support member, and the metal plate, a molding member disposed between the display panel, the cover member, the support member, the metal plate, and the frame, and a conductive member disposed between the molding member and the side surface of the display panel, the side surface of the support member, and the side surface of the metal plate at one side of the display panel adjacent to the optical area.

Other detailed matters of the exemplary embodiments are included in the detailed description and the drawings.

In the display device according to the embodiment of the present specification, the conductive member is disposed between the display panel and the molding member at one side of the display panel adjacent to the optical area, i.e., in the upper edge area of the display panel, such that the conductive member may serve as a buffer between the display panel and the molding member, which may reduce damage to the display panel.

In the display device according to the embodiment of the present specification, the conductive member is disposed between the display panel and the molding member at one side of the display panel adjacent to the optical area, i.e., in the upper edge area of the display panel, such that the conductive member may define the path through which static electricity generated on the cover member is discharged, which may improve the reliability of the display device.

In the display device according to another embodiment of the present specification, the light-blocking member is disposed on the inner surface of the through-hole disposed in the optical area, such that the light emitted from the plurality of subpixels of the display panel is inhibited from being transmitted into the through-hole, which may improve the reliability of the electronic optical device.

The effects according to the present disclosure are not limited to the contents exemplified above, and more various effects are included in the present specification.

It is to be understood that both the foregoing general description and the following detailed description of the present disclosure are by way of example and are intended to provide further explanation of the disclosure.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain the principles of the disclosure. In the drawings:

FIG. 1 is a block diagram for explaining a display device according to an embodiment of the present specification;

FIG. 2 is a view schematically illustrating a circuit configuration of a subpixel according to the embodiment of the present specification;

FIG. 3 is a top plan view of the display device according to the embodiment of the present specification;

FIG. 4 is a cross-sectional view taken along line IV-IV′ in FIG. 3;

FIG. 5 is a cross-sectional view taken along line V-V′ in FIG. 3;

FIG. 6 is a cross-sectional view of the subpixel according to the embodiment of the present specification;

FIG. 7 is a cross-sectional view taken along line VII-VII′ in FIG. 3;

FIG. 8 is an enlarged top plan view of area A in FIG. 3;

FIG. 9 is a cross-sectional view taken along line IX-IX′ in FIG. 8;

FIG. 10 is an enlarged top plan view of area A in FIG. 3 according to another embodiment of the present specification; and

FIG. 11 is a cross-sectional view taken along line XI-XI′ in FIG. 10.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present specification will be described with reference to the drawings.

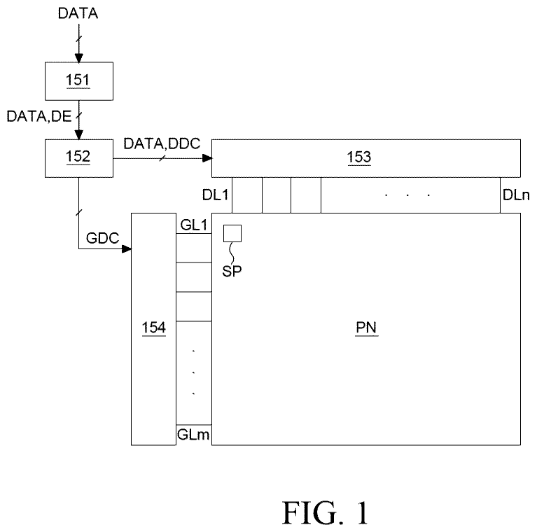

FIG. 1 is a block diagram for explaining a display device of an embodiment of the present specification.

With reference to FIG. 1, a display device of embodiments of the present disclosure may include an image processing part 151, a timing control part 152, a data drive part 153, a scan drive part 154, and a display panel PN.

The image processing part 151 may output a data signal DATA, a data enable signal DE, and the like supplied from the outside.

In addition, for example, the image processing part 151 may output one or more of a vertical synchronizing signal, a horizontal synchronizing signal, and a clock signal in addition to the data enable signal DE.

The timing control part 152 may receive the data signal DATA in addition to the data enable signal DE or the driving signals including the vertical synchronizing signal, the horizontal synchronizing signal, and the clock signal from the image processing part 151. In addition, on the basis of the driving signal, the timing control part 152 may output a gate timing control signal GDC for controlling an operation timing of the scan drive part 154 and output a data timing control signal DDC for controlling an operation timing of the data drive part 153.

In response to the data timing control signal DDC supplied from the timing control part 152, the data drive part 153 may sample and latch the data signal DATA supplied from the timing control part 152, convert the data signal DATA into a gamma reference voltage, and output the gamma reference voltage. The data drive part 153 may output the data signal DATA through data lines DL1 to DLn. The data drive part 153 may be provided in the form of an integrated circuit (IC).

In addition, the scan drive part 154 may output the scan signal in response to the gate timing control signal GDC supplied from the timing control part 152. The scan drive part 154 may output the scan signal through gate lines GL1 to GLm. The scan drive part 154 may be provided in the form of an integrated circuit (IC) or formed on the display panel PN in a gate-in-panel (GIP) manner.

The display panel PN may display an image in response to the data signal DATA and the scan signal supplied from the data drive part 153 and the scan drive part 154.

The display panel PN may include subpixels SP configured to display images.

For example, the subpixels SP may include a red subpixel, a green subpixel, and a blue subpixel or include a white subpixel, a red subpixel, a green subpixel, and a blue subpixel. The subpixel SP may have one or more different light-emitting areas depending on luminous properties.

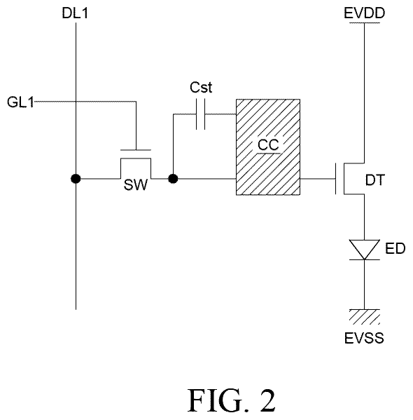

FIG. 2 is a view schematically illustrating a circuit configuration of the subpixel according to the embodiments of the present disclosure.

With reference to FIG. 2, one subpixel may include a switching transistor SW, a driving transistor DT, a capacitor Cst, a compensating circuit CC, and an organic light-emitting element ED.

For example, the switching transistor SW may perform a switching operation so that a data signal supplied through a first data line DL1 is stored, as a data voltage, in the capacitor Cst in response to a scan signal supplied through a first gate line GL1. In addition, for example, the driving transistor DT may operate such that a drive current flows between a first power line EVDD (high-potential voltage) and a second power line EVSS (low-potential voltage) in accordance with the data voltage stored in the capacitor Cst. In addition, the organic light-emitting element ED may operate to emit light in accordance with a drive current produced by the driving transistor DT.

The compensating circuit CC refers to a circuit added into the subpixel to compensate for a threshold voltage of the driving transistor DT or the like. The compensating circuit CC may include one or more transistors. The compensating circuit CC may have very various configurations depending on an external compensation method.

The subpixel illustrated in FIG. 2 has a 2T(Transistor)1C(Capacitor) structure including the switching transistor ST, the driving transistor DT, the capacitor Cst, and the light-emitting element 120. However, in case that the compensating circuit 135 is added, the subpixel may have various configurations such as 3T1C, 4T2C, 5T2C, 6TIC, 6T2C, 7T1C, 7T2C, or the like.

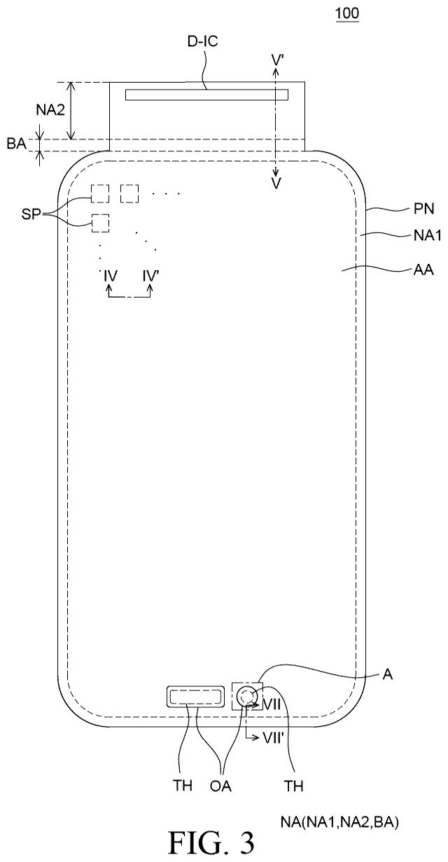

FIG. 3 is a top plan view of the display device according to the embodiment of the present specification. For convenience of description, FIG. 3 illustrates only the display panel PN and a data drive part D-IC among various constituent elements of a display device 100.

The display panel PN may include a display area AA, an optical area OA disposed in the display area AA and including through-holes TH, and a non-display area NA configured to surround the display area AA.

The display area AA is an area of the display panel PN in which images are displayed.

A plurality of subpixels SP and a circuit for operating the plurality of subpixels SP may be disposed in the display area AA. The plurality of subpixels SP may be minimum units that constitute the display area AA. Display elements may be respectively disposed in the plurality of subpixels SP. For example, an organic light-emitting element including an anode, a light-emitting layer, and a cathode may be disposed in each of the plurality of subpixels SP. However, the present specification is not limited thereto. In addition, the circuit configured to operate the plurality of subpixels SP may include driving elements, lines, and the like. For example, the circuit may include a thin-film transistor, a storage capacitor, a gate line, a data line, and the like. However, the present specification is not limited thereto.

The optical area OA is an area disposed in the display area AA, and the through-holes TH may be disposed in the optical area OA. The through-hole TH may be disposed in the display area AA of the display panel PN, thereby reducing a bezel area, which is the non-display area NA, and maximizing the display area AA. A design product with the maximized display area AA maximizes a degree of screen immersion of a user, thereby improving an aesthetic appearance.

The through-hole TH may be formed to correspond to an electronic optical device. The electronic optical device may be a device that receives light having passed through the display panel and performs a predetermined function in response to the received light. Therefore, the electronic optical device may be disposed to overlap the through-hole TH of the display panel PN. For example, the electronic optical device may be configured as a camera or various sensors. However, the present specification is not limited thereto. The electronic optical device may include all devices that perform predetermined functions in response to the light. Meanwhile, because the electronic optical device is disposed below the display panel PN, the electronic optical device may not be visually recognized by the user. For example, in case that the electronic optical device is a camera, the camera is disposed on the rear surface of the display panel PN. However, the camera may capture an image of the front surface of the display device 100 instead of the rear surface of the display device 100.

FIG. 3 illustrates two through-holes TH. However, the present specification is not limited thereto. The number of through-holes TH variously may be provided. For example, one or two holes are disposed in the display area AA. A camera may be disposed in a first hole, and a distance detection sensor, a face recognition sensor, or a wide angle camera may be disposed in a second hole.

The non-display area NA is an area in which no image is displayed. Various lines, various circuits, and the like for operating the display elements in the display area AA are disposed in the non-display area NA. For example, the non-display area NA may include link lines for transmitting signals to the plurality of subpixels and the circuit in the display area AA. The non-display area NDA may include gate-in-panel (GIP) lines or drive ICs such as the gate drive part and the data drive part D-IC.

The non-display area NA may be an area extending from the display area AA. However, the present specification is not limited thereto. The non-display area NA may be an area that surrounds the display area AA. FIG. 3 illustrates that the non-display area NA surrounds the display area AA having a round corner. However, the shapes and arrangements of the display area AA and the non-display area NA are not limited to the example illustrated in FIG. 3. That is, the display area AA and the non-display area NA may be suitable for the design of an electronic device equipped with the display device 100. For example, an exemplary shape of the display area AA may also be a quadrangular shape, a pentagonal shape, a hexagonal shape, a circular shape, an elliptical shape, or the like.

The non-display area NA includes a first non-display area NA1, a bending area BA, and a second non-display area NA2. The first non-display area NA1 is an area extending from the display area AA while surrounding the display area AA. The bending area BA may be an area extending from one side of the first non-display area NA1 and bent. The second non-display area NA2 may be an area extending from the bending area BA and disposed below the display area.

The first non-display area NA1 and the second non-display area NA2 may be areas disposed on the same plane as the display area AA or disposed in parallel with the display area AA and kept in a flat state. For example, the first non-display area NA1 may be disposed flat on the same plane as the display area AA, and the second non-display area NA2 may be disposed flat below the display area AA and disposed in parallel with the display area AA. Therefore, for example, the display area AA, the first non-display area NA1, and the second non-display area NA2 may be referred to as non-bending areas. However, the present specification is not limited thereto.

A drive IC D-IC may be disposed in the second non-display area NA2. The drive IC D-IC may provide data signals to the plurality of subpixels SP. For example, in response to the data timing control signal supplied from a timing controller, the drive IC D-IC may sample and latch a data signal supplied from the timing controller, convert the data signal into a gamma reference voltage, and output the gamma reference voltage. The drive IC D-IC may output the data signals through a plurality of data lines. For example, a pad part may be disposed in the second non-display area NA2 in which the drive IC D-IC is disposed, and a printed circuit board electrically connected to the pad part may be further disposed and provide a signal to the drive IC D-IC. However, the present specification is not limited thereto.

Meanwhile, the drive IC D-IC may be disposed in the form of a chip-on panel (COP) at one side of the display panel PN and connected to a display panel PN. Alternatively, the drive IC D-IC may be provided in the form of a chip-on film (COF) disposed on a separate flexible film and connected to the display panel PN. However, the present specification is not limited thereto.

As the display panel PN is bent, the drive IC D-IC disposed in the second non-display area NA2 is disposed below the display area AA. For example, the drive IC D-IC and the printed circuit board, which is connected to the pad part of the display panel PN, may move to a rear surface side of the display panel PN and overlap the display area AA. Therefore, the circuit elements, such as the drive IC D-IC and the printed circuit board, may not be visually recognized when viewed from above the display panel PN. Therefore, a size of the non-display area NA, which is visually recognized from above the display panel PN, may be reduced, such that a narrow bezel may be implemented.

The display device 100 may further include various additional elements configured to generate various signals or operate a pixel in the display area AA. The additional elements for operating the pixel may include an inverter circuit, a multiplexer, an electrostatic discharge (ESD) circuit, and the like. The display device 100 may also include additional elements related to functions other than the function of operating the pixel. For example, the display device 100 may further include additional elements that provide a touch detection function, a user certification function (e.g., fingerprint recognition), a multi-level pressure detection function, a tactile feedback function, and the like. The above-mentioned additional elements may be positioned in the non-display area NA and/or an external circuit connected to a connection interface.

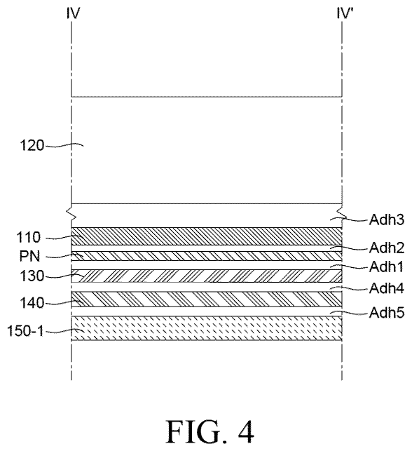

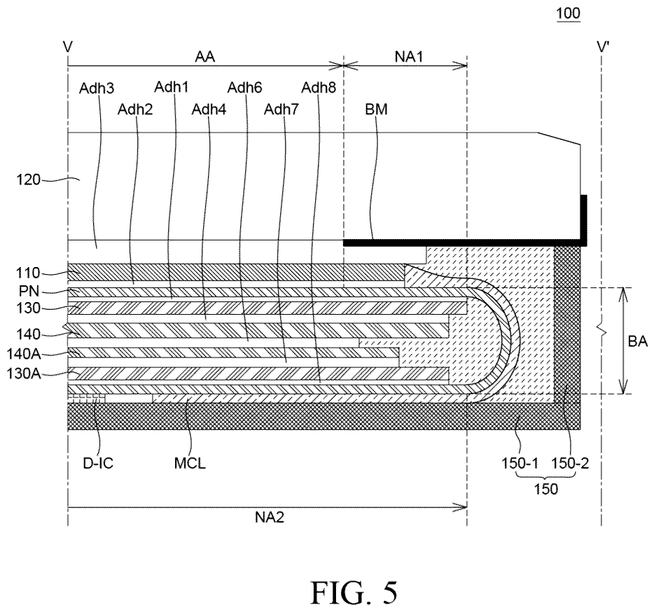

Hereinafter, the constituent elements of the display device 100 will be described in more detail with reference to FIGS. 4 and 5.

FIG. 4 is a cross-sectional view taken along line IV-IV′ in FIG. 1. FIG. 5 is a cross-sectional view taken along line V-V′ in FIG. 3.

With reference to FIGS. 4 and 5, the display device 100 may include a cover member 120, a polarizing layer 110, the display panel PN, a support member 130, a metal plate 140, a black matrix BM, a frame 150, and a molding member 160.

First, the display panel PN may include a substrate and light-emitting elements.

The substrate may be a support member for supporting other constituent elements disposed on the substrate of the display device 100, and the substrate may be made of an insulating material. For example, the substrate may be made of glass, resin, or the like. In addition, the substrate may include plastic such as polymer or polyimide (PI) and be made of a material having flexibility.

The light-emitting elements may be disposed on the substrate. The light-emitting elements may be differently defined depending on the type of display panel PN. For example, in case that the display panel PN is an organic light-emitting display panel, the light-emitting element may be an organic light-emitting diode (OLED).

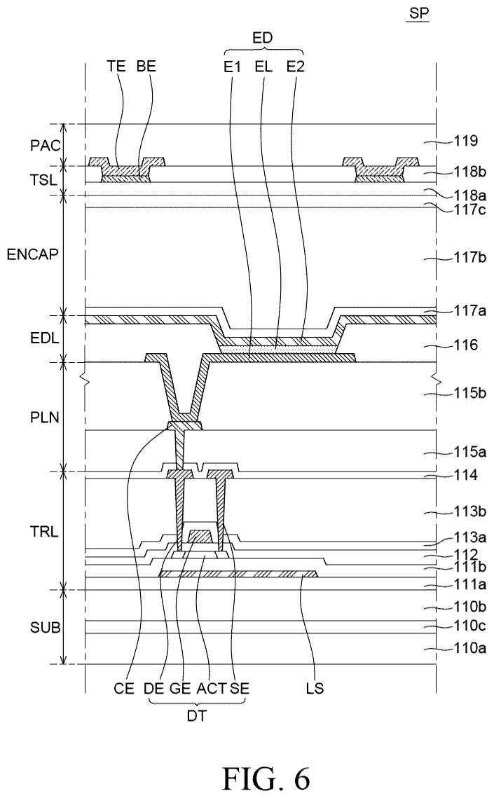

A driving transistor for operating the light-emitting element may be disposed between the substrate and the light-emitting element. The driving transistors may be respectively disposed in a plurality of subpixel areas. For example, the driving transistor may include a gate electrode, an active layer, a source electrode, and a drain electrode. In addition, the driving transistor may further include a gate insulation layer that insulates the gate electrode from the active layer, and the driving transistor may further include an interlayer insulation layer that insulates the gate electrode from the source electrode and the drain electrode. The display panel PN will be described in detail with reference to FIG. 6 to be described below.

The polarizing layer 110 may be disposed above the display panel PN. The polarizing layer 110 may be a layer for polarizing incident light. The polarizing layer 110 may be a film having light transmittance at a predetermined level and absorb external light and reflected light thereof to suppress a decrease in contrast ratio. Specifically, the display panel PN includes various metallic materials applied to semiconductor elements, lines, organic light-emitting elements, and the like. Therefore, the external light entering the display panel PN may be reflected by the metallic material. The reflection of external light may decrease visibility of the display device 100. Therefore, the polarizing layer 110 may be disposed to suppress the reflection of external light, thereby improving outdoor visibility of the display device 100.

A second bonding layer Adh2 may be disposed between the display panel PN and the polarizing layer 110. The second bonding layer Adh2 may fix the display panel PN and the polarizing layer 110. The second bonding layer Adh2 may minimize the occurrence of foreign substances or bubbles between the display panel PN and the polarizing layer 110, and an optically transparent bonding agent, such as an optically clear adhesive (OCA) or an optical clear resin (OCR), may be used. However, the present specification is not limited thereto.

The cover member 120 may be disposed on the polarizing layer 110. The cover member 120 may have a shape corresponding to the display panel PN and be disposed to cover the display panel PN. The cover member 120 may protect the display panel PN from an external impact, moisture, heat, or the like. For example, the cover member 120 may be a tempered glass. However, the present specification is not limited thereto.

With reference to FIG. 5, the black matrix BM may be disposed below the cover member 120. The black matrix BM may be disposed at an outer periphery of the cover member 120 and disposed along a periphery of the cover member 120. In this case, an area in which the black matrix BM is disposed may correspond to the first non-display area NA1. The black matrix BM may be made of a material with low permeability. Therefore, the black matrix BM may inhibit various constituent elements, which are disposed below the first non-display area NA1, from being visually recognized from the outside. In addition, the black matrix BM may be made of a material with conductivity and discharge static electricity of the cover member 120.

The black matrix BM may be made of resin containing chromium (Cr), graphite, or conductive particles. In this case, the resin may be one or more materials among acrylic resin, epoxy resin, phenolic resin, polyamide-based resin, polyimide-based resin, unsaturated polyester-based resin, polyphenylene-based resin, polyphenylene sulfide-based resin, and benzocyclobutene. However, the present specification is not limited thereto. In addition, the conductive particle may be made of any one of alloys of molybdenum (Mo), chromium (Cr), titanium (Ti), nickel (Ni), neodymium (Nd), copper (Cu), silver (Ag), and magnesium (Mg). However, the present specification is not limited thereto.

A third bonding layer Adh3 may be disposed between the polarizing layer 110 and the cover member 120. The third bonding layer Adh3 may fix the polarizing layer 110 and the cover member 120. The third bonding layer Adh3 may minimize the occurrence of foreign substances or bubbles between the polarizing layer 110 and the cover member 120, and an optically transparent bonding agent, such as an optically clear adhesive (OCA) or an optical clear resin (OCR), may be used. However, the present specification is not limited thereto.

Meanwhile, the support member 130 may be disposed below the display panel PN. The support member 130 may support the display panel PN and protect the display panel PN from external moisture, heat, impact, or the like. For example, the support member 130 may also be referred to as a backplate. The support member 130 may be made of a transparent organic insulating material to suppress curl and static electricity of the display device 100 and inspect an external appearance of the rear surface of the display device 100. For example, the support member 130 may be made of a plastic material such as polymethyl methacrylate (PMMA), polycarbonate (PC), polyvinyl alcohol (PVA), acrylonitrile-butadiene-styrene (ABS), polyethylene terephthalate (PET), silicone, and polyurethane (PU). However, the present specification is not limited thereto.

A first bonding layer Adh1 may be disposed between the support member 130 and the display panel PN. The first bonding layer Adh1 may fix the support member 130 and the display panel PN. The first bonding layer Adh1 may be a pressure sensitive bonding agent that minimizes the occurrence of foreign substances or bubbles between the support member 130 and the display panel PN. However, the present specification is not limited thereto.

The metal plate 140 may be disposed below the support member 130. The metal plate 140 may protect the support member 130 from an external impact that may be applied during the process of manufacturing the display device. In addition, the metal plate 140 may serve as a heat dissipation plate for dissipating heat, which is generated from the display panel PN, to the outside. The metal plate 140 may be made of a metallic material such as stainless steel (SUS), stainless steel (SUS) containing different metals such as nickel (Ni), iron (Fe), aluminum (Al), and magnesium (Mg). Particularly, stainless steel (SUS) may be applied to the metal plate 140. For example, because stainless steel (SUS) has high restoring force and rigidity, the metal plate 140 may maintain high rigidity even though a thickness of the metal plate 140 decreases.

A fourth bonding layer Adh4 may be disposed between the support member 130 and the metal plate 140. The fourth bonding layer Adh4 may fix the support member 130 and the metal plate 140. The fourth bonding layer Adh4 may be a pressure sensitive bonding agent or an optically transparent bonding agent, such as an optically clear adhesive or an optical clear resin, to minimize the occurrence of foreign substances or bubbles between the support member 130 and the metal plate 140. However, the present specification is not limited thereto.

With reference to FIGS. 3 and 5 together, an additional backplate 130A and an additional metal plate 140A may be disposed below the metal plate 140 corresponding to the bending area BA.

The additional backplate 130A and the additional metal plate 140A may complement the rigidity of the second non-display area NA2 of the display panel PN disposed in the second non-display area NA2. Meanwhile, the additional backplate 130A and the additional metal plate 140A may be disposed so as not to overlap the bending area BA. Therefore, thicknesses of the components disposed in the bending area BA may be minimized, and the flexibility of the bending area may be ensured by easily controlling a neutral surface of the bending area BA.

With reference to FIG. 5, a sixth bonding layer Adh6 is disposed between the metal plate 140 and the additional metal plate 140A, and a seventh bonding layer Adh7 is disposed between the additional metal plate 140A and the additional backplate 130A. The sixth bonding layer Adh6 may bond the metal plate 140 and the additional metal plate 140A, and the seventh bonding layer Adh7 may bond the additional metal plate 140A and the additional backplate 130A. For example, the sixth bonding layer Adh6 and the seventh bonding layer Adh7 may be configured as a pressure sensitive adhesive (PSA). However, the present specification is not limited thereto.

The second non-display area NA2 of the display panel PN is disposed below the additional backplate 130A. Further, an eighth bonding layer Adh8 is disposed between the additional backplate 130A and the second non-display area NA2 of the display panel PN. The eighth bonding layer Adh8 may bond the additional backplate 130A and the second non-display area NA2 of the display panel PN. For example, the eighth bonding layer Adh8 may be configured as a pressure sensitive adhesive (PSA). However, the present specification is not limited thereto.

The frame 150 is disposed below the metal plate 140. The frame 150 may be disposed below the metal plate 140 and disposed along the outer periphery of the display device 100. That is, the frame 150 may not only include a lower frame 150-1 disposed below the metal plate 140, but also include a lateral frame 150-2 connected to the lower frame 150-1 and configured to surround a side surface of the display device 100. Therefore, the frame 150 may reinforce the rigidity of the outer periphery of the display device 100.

For example, the frame 150 may be made of plastic, such as polyimide (PI), polyethylene naphthalate (PEN), polyethylene terephthalate (PET), or a combination of these polymer, or metal, such as copper (Cu) or stainless steel (SUS), to reinforce the rigidity of the outer periphery of the display device 100. However, the present specification is not limited thereto.

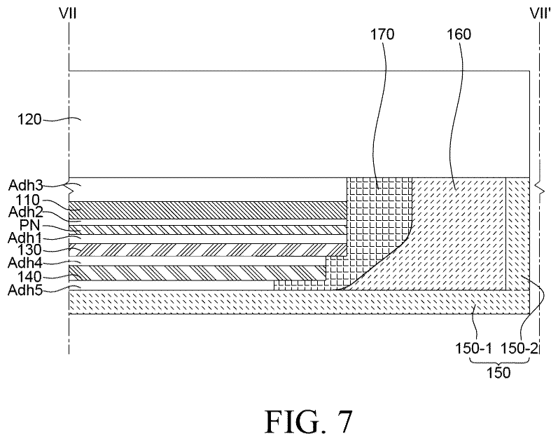

In addition, the molding member 160, which fills a space provided by the frame 150, may be included. The molding member 160 will be described in detail with reference to FIG. 7 to be described below.

A fifth bonding layer Adh5 may be disposed between the metal plate 140 and the frame 150. The fifth bonding layer Adh5 may fix the metal plate 140 and the frame 150. The fifth bonding layer Adh5 may be a pressure sensitive bonding agent that minimizes the occurrence of foreign substances or bubbles between the metal plate 140 and the frame 150. However, the present specification is not limited thereto.

With reference to FIGS. 3 and 5, a coating layer MCL may be disposed in the bending area BA of the display panel PN. For example, the coating layer MCL may be disposed to adjoin one side of the polarizing layer 110 disposed on the display panel PN. The display panel PN may be finely cracked because a tensile force is applied to the display panel PN when the display panel PN is bent. Therefore, the coating layer MCL may be formed by coating the bending area with resin with a small thickness, thereby protecting the display panel PN.

For example, the coating layer MCL may be disposed to adjoin one end of the polarizing layer 110 disposed in the first non-display area NA1, and the coating layer MCL may extend to the bending area BA and the second non-display area NA2. For example, an area between the polarizing layer 110 in the first non-display area NA1 and the drive IC D-IC disposed in the second non-display area NA2 may be coated with the coating layer MCL. For example, one end of the coating layer MCL may adjoin the polarizing layer 110 of the first non-display area NA1, and the other end of the coating layer MCL may adjoin the drive IC D-IC disposed in the second non-display area NA2. However, the present specification is not limited thereto. The other end of the coating layer MCL may be spaced apart from the drive IC D-IC disposed in the second non-display area NA2.

Hereinafter, the constituent elements of the display panel PN will be described in more detail with reference to FIG. 6.

FIG. 6 is a cross-sectional view illustrating a cross-sectional structure of one subpixel disposed in the display area according to the embodiment of the present specification. Specifically, FIG. 6 illustrates only the constituent elements included in the display panel PN in one subpixel SP disposed in the display area AA.

With reference to FIG. 6, in the subpixel SP disposed in the display area AA, a transistor layer TRL may be disposed above a substrate SUB, and a planarization layer PLN may be disposed above the transistor layer TRL. In addition, a light-emitting element layer EDL may be disposed above the planarization layer PLN, an encapsulation layer ENCAP may be disposed above the light-emitting element layer EDL, a touch sensing layer TSL may be disposed above the encapsulation layer ENCAP, and a protective layer PAC may be disposed above the touch sensing layer TSL. In addition, a polarizing layer POL may be disposed above the protective layer PAC.

The substrate SUB is a component for supporting various constituent elements included in the display device 100 and may be made of an insulating material. The substrate SUB may include a first substrate 110a, a second substrate 110b, and an interlayer insulation layer 110c. The interlayer insulation layer 110c may be disposed between the first substrate 110a and the second substrate 110b. As described above, the substrate SUB may include the first substrate 110a, the second substrate 110b, and the interlayer insulation layer 110c, which may suppress moisture penetration. For example, the first substrate 110a and the second substrate 110b may each be a substrate made of polyimide (PI).

Various types of patterns GE, DE, SE, and ACT for forming a transistor such as the driving transistor DT, various types of insulation layers 111a, 111b, 112, 113a, 113b, and 114, and various types of metal patterns LS may be disposed on the transistor layer TRL in the display area AA.

Hereinafter, a layered structure of the transistor layer TRL will be described in more detail.

A multi-buffer layer 111a may be disposed on the second substrate 110b, and an active buffer layer 111b may be disposed on the multi-buffer layer 111a.

A light-blocking layer LS, which serves as a light shield, may be disposed on the multi-buffer layer 111a.

The active buffer layer 111b may be disposed on the light-blocking layer LS.

An active layer ACT of the driving transistor DT may be disposed on the active buffer layer 111b. For example, the active layer ACT may be made of polysilicon (p-Si), amorphous silicon (a-Si), or oxide semiconductor. However, the present specification is not limited thereto.

A gate insulation layer 112 may be disposed on the active layer ACT. The gate insulation layer 112 may be made of silicon oxide (SiOₓ), silicon nitride (SiNₓ), or a multilayer thereof.

In addition, a gate electrode GE of the driving transistor DT may be disposed on the gate insulation layer 112. The gate electrode GE is disposed on the gate insulation layer 112 and overlaps the active layer ACT. The gate electrode GE may be made of various electrically conductive materials, for example, magnesium (Mg), aluminum (Al), nickel (Ni), chromium (Cr), molybdenum (Mo), tungsten (W), gold (Au), or an alloy thereof. However, the present specification is not limited thereto.

A first interlayer insulation layer 113a may be disposed to cover the gate electrode GE. A second interlayer insulation layer 113b may be disposed on the first interlayer insulation layer 113a.

A source electrode SE and a drain electrode DE of the driving transistor DT may be disposed on the second interlayer insulation layer 113b.

The source electrode SE and the drain electrode DE may be respectively connected to one side and the other side of the active layer ACT through contact holes provided in the second interlayer insulation layer the 113b, first interlayer insulation layer 113a, and the gate insulation layer 112. The source electrode SE and the drain electrode DE may each be made of various electrically conductive materials, for example, magnesium (Mg), aluminum (Al), nickel (Ni), chromium (Cr), molybdenum (Mo), tungsten (W), gold (Au), or an alloy thereof. However, the present specification is not limited thereto.

A portion of the active layer ACT, which overlaps the gate electrode GE, may be a channel area. One of the source electrode SE and the drain electrode DE is connected to one side of the channel area of the active layer ACT, and the other of the source electrode SE and the drain electrode DE is connected to the other side of the channel area of the active layer ACT.

A passivation layer 114 may be disposed on the source electrode SE and the drain electrode DE. The passivation layer 114 may serve to protect the driving transistor DT and be configured as an inorganic layer, for example, silicon oxide (SiOₓ), silicon nitride (SiNₓ), or a multilayer thereof.

The planarization layer PLN may be positioned above the transistor layer TRL.

The planarization layer PLN may include a first planarization layer 115a and a second planarization layer 115b. The planarization layer PLN protects the driving transistor DT and planarizes the upper portion of the driving transistor DT.

The first planarization layer 115a may be disposed on the passivation layer 114.

A connection electrode CE may be disposed on the first planarization layer 115a.

The connection electrode CE may be connected to one of the source electrode SE and the drain electrode DE through a contact hole provided in the first planarization layer 115a.

The second planarization layer 115b may be disposed on the connection electrode CE.

The light-emitting element layer EDL may be positioned above the second planarization layer 115b.

Hereinafter, a layered structure of the light-emitting element layer EDL will be described in detail.

An anode E1 may be disposed on the second planarization layer 115b. In this case, the anode E1 may be electrically connected to the connection electrode CE through a contact hole provided in the second planarization layer 115b. The anode E1 may be made of a metallic material.

In case that the display device 100 is a top-emission type display device in which light emitted from the light-emitting element ED propagates toward an upper side of the substrate SUB on which the light-emitting element ED is disposed, the anode E1 may further include a transparent conductive layer and a reflective layer disposed below the transparent conductive layer. For example, the transparent conductive layer may be made of transparent conductive oxide such as ITO or IZO. For example, the reflective layer may be made of silver (Ag), aluminum (Al), gold (Au), molybdenum (Mo), tungsten (W), chromium (Cr), or an alloy thereof.

A bank 116 may be disposed to cover the anode E1. A portion of the bank 116, which corresponds to the light-emitting area of the subpixel, may be opened. A part of the anode E1 may be exposed through the opened portion (hereinafter, referred to as an open area) of the bank 116. In this case, the bank 116 may be made of an inorganic insulating material such as silicon nitride (SiNₓ) or silicon oxide (SiOₓ), or an organic insulating material such as benzocyclobutene-based resin, acrylic resin, or imide-based resin. However, the present specification is not limited thereto.

A light-emitting layer EL may be disposed in the open area of the bank 116. Therefore, the light-emitting layer EL may be disposed on the anode E1 exposed through the open area of the bank 116.

A cathode E2 may be disposed on the light-emitting layer EL.

The light-emitting element ED may be formed by the anode E1, the light-emitting layer EL, and the cathode E2. The light-emitting layer EL may include a plurality of organic layers.

The encapsulation layer ENCAP may be positioned above the light-emitting element layer EDL.

The encapsulation layer ENCAP may have a single-layer or multilayer structure. For example, the encapsulation layer ENCAP may include a first encapsulation layer 117a, a second encapsulation layer 117b, and a third encapsulation layer 117c.

In this case, the first encapsulation layer 117a and the third encapsulation layer 117c may each be configured as an inorganic layer, and the second encapsulation layer 117b may each be configured as an organic layer. Among the first encapsulation layer 117a, the second encapsulation layer 117b, and the third encapsulation layer 117c, the second encapsulation layer 117b may be thickest and serve as a planarization layer.

The first encapsulation layer 117a may be disposed on the cathode E2 and closest to the light-emitting element ED. The first encapsulation layer 117a may be made of an inorganic insulating material that may be deposited at a low temperature. For example, the first encapsulation layer 117a may be made of silicon nitride (SiNₓ), silicon oxide (SiOₓ), silicon oxynitride (SiON), aluminum oxide (Al₂O₃), or the like. Because the first encapsulation layer 117a is deposited in a low-temperature ambience, it is possible to suppress damage to the light-emitting layer EL made of an organic material vulnerable to a high-temperature ambience during a deposition process.

The second encapsulation layer 117b may have a smaller area than the first encapsulation layer 117a. In this case, the second encapsulation layer 117b may be formed to expose two opposite ends of the first encapsulation layer 117a. The second encapsulation layer 117b may serve as a buffer for mitigating stress between the layers. The second encapsulation layer 117b may serve to improve the planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present specification is not limited thereto.

The third encapsulation layer 117c may be formed on the upper portion of the substrate SUB having the second encapsulation layer 117b to cover a top surface and a side surface of each of the second encapsulation layer 117b and the first encapsulation layer 117a. In this case, the third encapsulation layer 117c may minimize or block the penetration of outside moisture or oxygen into the first encapsulation layer 117a and the second encapsulation layer 117b. For example, the third encapsulation layer 117c may be made of an inorganic insulating material such as silicon nitride (SiNₓ), silicon oxide (SiOₓ), silicon oxynitride (SiON), or aluminum oxide (Al₂O₃).

The touch sensing layer TSL may be disposed above the encapsulation layer ENCAP.

Specifically, the touch sensing layer TSL may include a touch buffer layer 118a disposed on the encapsulation layer ENCAP, a bridge electrode BE disposed on the touch buffer layer 118a, a touch interlayer insulation layer 118b disposed on the touch buffer layer 118a and the bridge electrode BE, and a plurality of touch electrodes TE disposed on the touch interlayer insulation layer 118b.

The touch buffer layer 118a may inhibit outside moisture, foreign substances, or a liquid chemical such as a developer or an etching liquid, which is used during a process of manufacturing the touch electrodes formed on the touch buffer layer 118a, from penetrating into the light-emitting element.

The plurality of touch electrodes TE may include a plurality of first touch electrodes extending in a first direction, and a plurality of second touch electrodes extending in a second direction intersecting the first direction.

For example, the plurality of first touch electrodes and the plurality of second touch electrodes may be disposed on the same layer. However, the plurality of second touch electrodes may be disposed to be separated from one another in the area in which the plurality of first touch electrodes and the plurality of second touch electrodes intersect. The plurality of second touch electrodes, which are separated from one another, may be connected by the bridge electrodes BE. The touch interlayer insulation layers 118b may be disposed between the plurality of second touch electrodes and the bridge electrodes BE.

A protective layer PAC (119) may be disposed to cover the touch sensing layer TSL. The protective layer 119 may be configured as an organic insulation layer. The protective layer 119 may suppress a level difference on the uppermost layer of the display device 100, thereby improving the visibility of the display device 100.

Hereinafter, one side of the display device 100 adjacent to the optical area OA, i.e., an upper edge area of the display device 100 will be described in more detail with reference to FIG. 7.

FIG. 7 is a cross-sectional view taken along line VII-VII′ in FIG. 3. A repeated description of the constituent elements substantially identical to the constituent elements illustrated in FIGS. 4 and 5 will be omitted. The same reference numerals are used for the same components.

With reference to FIG. 7, in the display device 100 according to the embodiment of the present specification, one side of the display device 100 adjacent to the optical area OA may include the cover member 120, the polarizing layer 110, the display panel PN, the support member 130, the metal plate 140, the frame 150, and a molding member 160, like the display area AA of the display device 100.

In the display device 100 according to the embodiment of the present specification, the frame 150 may be disposed below the metal plate 140 and disposed along the outer periphery of the display device 100. That is, the frame 150 may not only include the lower frame 150-1 disposed below the metal plate 140, but also include the lateral frame 150-2 connected to the lower frame 150-1 and configured to surround the side surface of the display device 100.

The display device 100 according to the embodiment of the present specification may include the molding member 160 configured to fill a space provided by the frame 150. For example, the molding member 160 may be disposed between the frame 150 and the cover member 120, the polarizing layer 110, the display panel PN, the support member 130, and the metal plate 140. The molding member 160 may be formed to seal a lower portion of the cover member 120, a side surface of the polarizing layer 110, a side surface of the display panel PN, a side surface of the support member 130, and a side surface of the metal plate 140. Because the molding member 160 seals the lower portion of the cover member 120, the side surface of the polarizing layer 110, the side surface of the display panel PN, the side surface of the support member 130, and the side surface of the metal plate 140, it is possible to suppress the penetration of moisture, oxygen, or foreign substances into the display device 100. In addition, the molding member 160 may protect the constituent elements of the display device 100 and mitigate an impact to be applied to the display device 100.

For example, the molding member 160 may be formed by filling the inside of the frame 150 with the material, which constitutes the molding member 160, and curing the material. However, the method of forming the molding member 160 is not limited thereto.

The molding member 160 may include curable resin. For example, the molding member 160 may be made of one or more materials among acrylic resin, epoxy resin, phenolic resin, polyamide-based resin, polyimide-based resin, unsaturated polyester-based resin, polyphenylene-based resin, polyphenylene sulfide-based resin, and benzocyclobutene. However, the present specification is not limited thereto.

In the display device 100 according to the embodiment of the present specification, a conductive member 170 is disposed between the side surface of the display panel PN and the molding member 160 at one side of the display panel PN adjacent to the optical area OA, i.e., the upper edge of the display panel PN. For example, the conductive member 170 may not only be disposed on the side surface of the display panel PN, but also be disposed between the lower portion of the cover member 120, the side surface of the polarizing layer 110, the side surface of the support member 130, the side surface of the metal plate 140, and the molding member 160.

In the display device 100 according to the embodiment of the present specification, the conductive member 170 may serve as a buffer between the display panel PN and the molding member 160, thereby inhibiting the display panel PN from cracking.

In the display device 100 according to the embodiment of the present specification, the conductive member 170 may be connected between the cover member 120 and the metal plate 140. The conductive member 170 may be made of a material excellent in electrical conductivity and discharge static electricity, which is generated by the cover member 120, to the outside. Specifically, the metal plate 140 may be electrically grounded and configured to discharge static electricity. The conductive member 170, which is connected between the cover member 120 and the metal plate 140, may define a path through which the static electricity generated on the cover member 120 is discharged. Therefore, in the display device 100 according to the embodiment of the present specification, the conductive member 170, which connects the cover member 120 and the metal plate 140, may discharge static electricity from the cover member 120, such that the static electricity may be inhibited from being accumulated on or introduced into the display panel PN, thereby improving the reliability of the display device 100.

In the display device 100 according to the embodiment of the present specification, a material with a low modulus may be applied to the conductive member 170. Specifically, the conductive member 170 may be conductive ink having a modulus of 200 MPa or lower, more particularly, 150 MPa or lower.

In the display device 100 according to the embodiment of the present specification, the conductive member 170 may be made of conductive ink made by mixing conductive particles, such as carbon black, and conductive polymer, such as PEDOT:PSS (poly(3,4-ethylenedioxythiophene)), or conductive paste made of a material such as silver. However, the present specification is not limited thereto.

After the display device 100 is manufactured, a reliability evaluation process, in which a high temperature and a low temperature are repeatedly provided, may be performed to identify stability of a product. In the related art, because there is no gap between a display panel and a molding member, there is a problem in that stress, which is caused by contraction and expansion of the molding member, accumulates on an edge of the display panel, which is in contact with the molding member, during the reliability evaluation process. Particularly, the stress, which accumulates on the edge of the through-hole, causes a growing dark spot (GDS) defect on the edge of the through-hole.

Therefore, in the display device 100 according to the embodiment of the present specification, the conductive member 170 having a modulus of 200 MPa or lower is disposed between the display panel PN and the molding member 160. Therefore, even though stress is caused by the repeated contraction or expansion of the molding member 160 in a high-temperature or low-temperature environment, the conductive member 170 may serve as a buffer between the display panel PN and the molding member 160, which may inhibit the stress from accumulating on one side of the display panel PN, particularly, the edge of the through-hole TH. Therefore, it is possible to improve the reliability of the display device 100.

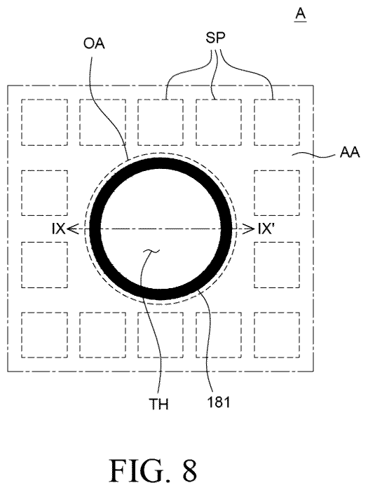

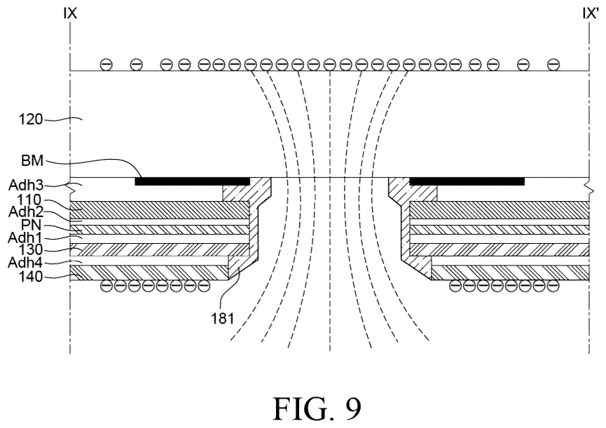

FIG. 8 is an enlarged top plan view of area A in FIG. 3. FIG. 9 is a cross-sectional view taken along line IX-IX′ in FIG. 8. For convenience of description, FIG. 9 illustrates only the cover member 120, the third bonding layer Adh3, the polarizing layer 110, the second bonding layer Adh2, the display panel PN, the first bonding layer Adh1, the support member 130, the fourth bonding layer Adh4, the metal plate 140, and a first light-blocking member 181 among various constituent elements of the display device 100.

With reference to FIGS. 3, 8, and 9 together, in the display device 100 according to the embodiment of the present specification, the optical area OA, which includes the through-hole TH formed through some constituent elements of the display device 100, is disposed in the display area AA in which the plurality of subpixels SP is disposed.

In the display device 100 according to the embodiment of the present specification, the first light-blocking member 181 is disposed to cover an edge of a rear surface of the cover member 120 exposed by the through-hole TH and cover an inner surface of the through-hole TH.

The first light-blocking member 181 may be made of a material with moisture resistance and disposed to cover the entire metal plate 140 at the edge of the rear surface of the cover member 120 exposed by the through-hole TH. Specifically, the first light-blocking member 181 may cover the side surfaces of the polarizing layer 110, the display panel PN, the support member 130, and the metal plate 140 disposed in the through-hole TH. The first light-blocking member 181 may be disposed to cover a part of the rear surface of the cover member 120 corresponding to an inner peripheral surface of the through-hole TH and a periphery of the through-hole TH. Therefore, the first light-blocking member 181 may inhibit moisture or water, which penetrates into the through-hole TH, from penetrating into the polarizing layer 110, the display panel PN, the support member 130, and the metal plate 140 disposed along the through-hole TH.

The first light-blocking member 181 may include a conductive material or a non-conductive material. The first light-blocking member 181 may suppress a leak of light that is caused when the light emitted from the plurality of subpixels SP of the display panel PN is introduced into the through-hole TH.

In case that the first light-blocking member 181 includes a conductive material, the first light-blocking member 181 may be made of conductive ink or conductive paste. For example, the first light-blocking member 181 may be made of conductive ink made by mixing conductive particles, such as carbon black, and conductive polymer, as such PEDOT:PSS (poly(3,4-ethylenedioxythiophene)), or conductive paste made of a material such as silver. However, the present specification is not limited thereto.

In case that the first light-blocking member 181 includes a non-conductive material, the first light-blocking member 181 may be made of non-conductive ink or non-conductive paste. For example, the first light-blocking member 181 may be made of a material in which a trace amount of carbon black is included in a curable bonding agent. However, the present specification is not limited thereto. For example, in case that the first light-blocking member 181 includes a non-conductive material, process costs may be reduced in comparison with a case in which the first light-blocking member 181 includes a conductive material.

In addition, the black matrix BM may be disposed below the cover member 120 and disposed along the periphery of the through-hole TH. In this case, the black matrix BM may be made of a material with low permeability. Therefore, the black matrix BM may inhibit various constituent elements, which overlap the black matrix BM, from being visually recognized from the outside in the vicinity of the through-hole TH. In addition, the black matrix BM may be made of a material with conductivity and discharge static electricity of the cover member 120.

The black matrix BM may be made of resin containing chromium (Cr), graphite, or conductive particles. In this case, the resin may be one or more materials among acrylic resin, epoxy resin, phenolic resin, polyamide-based resin, polyimide-based resin, unsaturated polyester-based resin, polyphenylene-based resin, polyphenylene sulfide-based resin, and benzocyclobutene. However, the present specification is not limited thereto. In addition, the conductive particle may be made of any one of alloys of molybdenum (Mo), chromium (Cr), titanium (Ti), nickel (Ni), neodymium (Nd), copper (Cu), silver (Ag), and magnesium (Mg). However, the present specification is not limited thereto.

In general, after the display device is manufactured, a static electricity evaluation process using a brass rod is performed to identify stability of a product. In this case, electric charges may be generated on the surface of the display device 100, i.e., the cover member 120 by physical friction or the like. In the related art, in case that generated electric charges cannot be discharged to the outside through a ground path, there is a problem in that electric charges concentratedly accumulate at one end of the display panel, i.e., one end of the display panel adjacent to the through-hole. In case that electric charges are accumulated in a particular area as described above, static electricity may be formed in proportion to the quantity of accumulated electric charges. When static electricity is generated at one end of the display panel, one end of the display panel becomes brighter than the display area of the display panel, which degrades reliability of the display device.

In addition, in the related art, there is a problem in that the light emitted from the plurality of subpixels SP leaks while being transmitted into the through-hole TH. In this case, the light emitted from the plurality of subpixels SP acts as noise and inhibits the electronic optical device disposed in the through-hole TH from recognizing external light, which causes a problem in that the reliability of the electronic optical device deteriorates.

Therefore, in the display device 100 according to the embodiment of the present specification, the conductive member 170 is disposed between the side surface of the display panel PN and the molding member 160 at one side of the display panel PN adjacent to the optical area OA, such that static electricity generated on the cover member 120 may be discharged to the metal plate 140. For example, the metal plate 140 may be electrically grounded and configured to discharge static electricity. Therefore, the conductive member 170 may be connected between the cover member 120 and the metal plate 140 and define a path through which static electricity generated on the cover member 120 is discharged. Therefore, in the display device 100 according to the embodiment of the present specification, the conductive member 170, which connects the cover member 120 and the metal plate 140, may discharge static electricity from the cover member 120, such that the static electricity may be inhibited from being accumulated on or introduced into the display panel PN, thereby improving the reliability of the display device 100.

In addition, in the display device 100 according to the embodiment of the present specification, the first light-blocking member 181 may be disposed to cover the inner surface of the through-hole TH and inhibit the light emitted from the plurality of subpixels SP from being transmitted into the through-hole TH, which may improve the reliability of the electronic optical device.

In addition, in case that the first light-blocking member 181 is made of a conductive material, the first light-blocking member 181 connects the cover member 120 and the metal plate 140 on the inner surface of the through-hole TH, such that a path, through which static electricity generated on the cover member 120 is discharged, may be additionally formed. Therefore, it is possible to improve the reliability of the display device 100 by inhibiting static electricity from being accumulated on or introduced into the display panel PN. However, because one side of the display panel PN, at which the conductive member 170 is disposed, is close to the optical area OA in which the through-hole TH is disposed, a current application effect in the through-hole TH may be achieved by the conductive member 170 even though the first light-blocking member 181 is made of a non-conductive material.

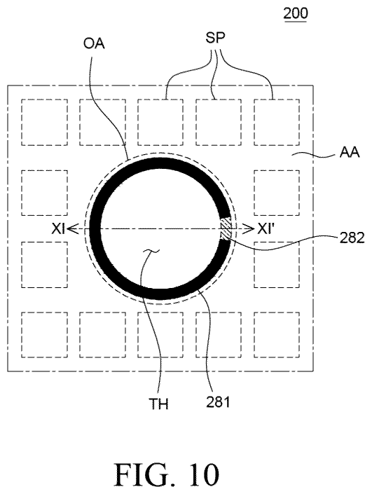

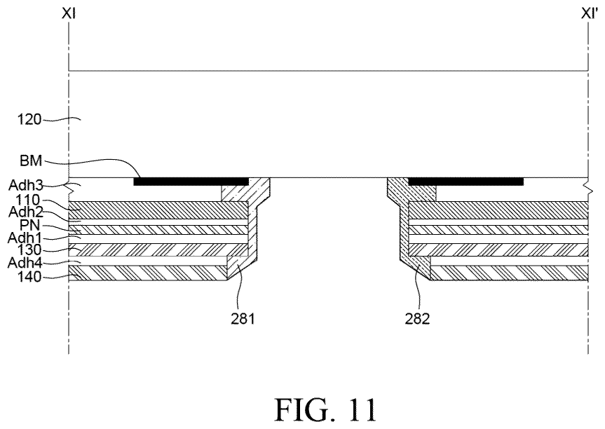

FIG. 10 is an enlarged top plan view of area A in FIG. 3 according to another embodiment of the present specification. FIG. 11 is a cross-sectional view taken along line XI-XI′ in FIG. 10. A display device having area A illustrated in FIG. 10 is substantially identical in configuration to the display device in FIGS. 1 to 9, except for a first light-blocking member 281 and a second light-blocking member 282. Therefore, repeated descriptions of the identical components will be omitted. The same reference numerals are used for the same components. Hereinafter, the components denoted by the same reference numerals will be described with reference to FIGS. 1 to 9.

With reference to FIGS. 3, 10, and 11 together, in a display device 200 according to another embodiment of the present specification, the optical area OA, which includes the through-hole TH formed through some constituent elements of the display device 200, is disposed in the display area AA in which the plurality of subpixels SP is disposed.

In the display device 200 according to the embodiment of the present specification, the first light-blocking member 281 is disposed to cover a part of the edge of the rear surface of the cover member 120 exposed by the through-hole TH and cover a part of the inner surface of the through-hole TH.

The first light-blocking member 281 may be made of a material with moisture resistance and disposed to cover the entire metal plate 140 at the edge of the rear surface of the cover member 120 exposed by the through-hole TH. Specifically, the first light-blocking member 181 may cover the side surfaces of the polarizing layer 110, the display panel PN, the support member 130, and the metal plate 140 disposed in the through-hole TH. The first light-blocking member 281 may be disposed to cover a part of the rear surface of the cover member 120 corresponding to the inner peripheral surface of the through-hole TH and the periphery of the through-hole TH. Therefore, the first light-blocking member 281 may inhibit moisture or water, which penetrates into the through-hole TH, from penetrating into the polarizing layer 110, the display panel PN, the support member 130, and the metal plate 140 disposed along the through-hole TH.

The first light-blocking member 281 may include a non-conductive material. The first light-blocking member 281 may inhibit the light emitted from the plurality of subpixels SP of the display panel PN from being introduced into the through-hole TH.

The display device 200 according to another embodiment of the present specification may further include the second light-blocking member 282 configured to cover the remaining part of the edge of the rear surface of the cover member 120 exposed by the through-hole TH and cover the remaining part of the inner surface of the through-hole TH. For example, the first light-blocking member 281 may cover a part of the inner surface of the through-hole TH, and the second light-blocking member 282 may cover the remaining part of the through-hole TH that is not covered by the first light-blocking member 281.

The second light-blocking member 282 may be a conductive pattern having conductivity. For example, the second light-blocking member 282 may be made of conductive ink or conductive paste. The second light-blocking member 282 may be made of conductive ink made by mixing conductive particles, such as carbon black, and conductive polymer, such as PEDOT:PSS (poly(3,4-ethylenedioxythiophene)), or conductive paste made of a material such as silver. However, the present specification is not limited thereto.

For example, a material for forming the first light-blocking member 281 may be applied onto at least a partial area of the inner surface of the through-hole TH, and then a material for forming the second light-blocking member 282 may be applied onto the remaining area in which the material for forming the first light-blocking member 281 is not applied. However, the method of forming the first light-blocking member 281 and the second light-blocking member 282 is not limited thereto. Therefore, a part of the inner surface of the through-hole TH may be covered by the first light-blocking member 281 made of a non-conductive material, and the remaining part of the through-hole TH, which is not covered by the first light-blocking member 281, may be covered by the second light-blocking member 282 made of a conductive material.

An area of the second light-blocking member 282 may be smaller than an area of the first light-blocking member 281. For example, the second light-blocking member 282 may have a dot shape, a partially annular sector shape, or a partially annular shape. However, the present specification is not limited thereto.

In general, after the display device is manufactured, a static electricity evaluation process using a brass rod is performed to identify stability of a product. In this case, electric charges may be generated on the surface of the display device 100, i.e., the cover member 120 by physical friction or the like. In the related art, in case that generated electric charges cannot be discharged to the outside through a ground path, there is a problem in that electric charges concentratedly accumulate at one end of the display panel, i.e., one end of the display panel adjacent to the through-hole. In case that electric charges are accumulated in a particular area as described above, static electricity may be formed in proportion to the quantity of accumulated electric charges. When static electricity is generated at one end of the display panel, one end of the display panel becomes brighter than the display area of the display panel, which degrades reliability of the display device.

In addition, in the related art, there is a problem in that the light emitted from the plurality of subpixels SP leaks while being transmitted into the through-hole TH. In this case, the light emitted from the plurality of subpixels SP acts as noise and inhibits the electronic optical device disposed in the through-hole TH from recognizing external light, which causes a problem in that the reliability of the electronic optical device deteriorates.

Therefore, in the display device 200 according to the embodiment of the present specification, the conductive member 170 is disposed between the side surface of the display panel PN and the molding member 160 at one side of the display panel PN adjacent to the optical area OA, such that static electricity generated on the cover member 120 may be discharged to the metal plate 140. The metal plate 140 may be electrically grounded and configured to discharge static electricity. The conductive member 170 may be connected between the cover member 120 and the metal plate 140 and define a path through which static electricity generated on the cover member 120 is discharged. Therefore, in the display device 200 according to the embodiment of the present specification, the conductive member 170, which connects the cover member 120 and the metal plate 140, may discharge static electricity from the cover member 120, such that the static electricity may be inhibited from being accumulated on or introduced into the display panel PN, thereby improving the reliability of the display device 200.

In addition, in the display device 200 according to the embodiment of the present specification, the first light-blocking member 281 is disposed to cover at least a part of the inner surface of the through-hole TH, and the second light-blocking member 282 is disposed to cover the remaining part of the inner surface of the through-hole TH, such that the light emitted from the plurality of subpixels SP is inhibited from being transmitted into the through-hole TH, which may improve the reliability of the electronic optical device.

In addition, the first light-blocking member 281 is made of a non-conductive material, which may achieve an effect of reducing process costs. The second light-blocking member 282 having a smaller area than the first light-blocking member 281 is disposed, and the second light-blocking member 282 connects the cover member 120 and the metal plate 140 on at least a part of the inner surface of the through-hole TH, which may additionally define a path through which static electricity generated on the cover member 120 is discharged. Therefore, it is possible to improve the reliability of the display device 200 by inhibiting static electricity from being accumulated on or introduced into the display panel PN.

Hereinafter, the effect according to the embodiment of the present disclosure described above will be described in more detail with reference to Embodiments and Comparative Embodiment.

First, Embodiment shown in Table 1 below is the display device 100 according to the embodiment of the present specification. In this case, conductive ink having a modulus of 150 MPa was applied as the conductive member 170.

In addition, Embodiment 2 has the same structure as Embodiment 1 but differs from Embodiment 1 in terms of the modulus of the conductive member 170. Specifically, conductive ink having a modulus of 84 MPa was applied as the conductive member 170 of Embodiment 2.

Meanwhile, Comparative Embodiment differs from Embodiment 1 in terms of the structure in which the display panel PN and the molding member 160 are in contact with each other at one side of the display device 100 adjacent to the optical area OA in Embodiment 1. That is, the display device of Comparative Embodiment has a structure in which no conductive member is disposed between the display panel PN and the molding member 160 at one side of the display device 100 adjacent to the optical area OA.

Maximum main stress at the edges of the through-holes TH disposed in the display panels PN was measured while the display devices of Embodiments and Comparative Embodiment were alternately exposed to a high-temperature (65° C.) environment and a low-temperature (−25° C.) environment. The maximum main stress is shown in Table 1 below. In this case, the maximum main stress means normal stress when only the normal stress is applied to any surface including any one point in an object, which receives an external force, whereas shear stress is not applied to the surface.

TABLE 1

Maximum main stress (MPa)

| | High temperature | Low temperature |
|---|---|---|
| Classification | (65° C.) | (−20° C.) |
| Embodiment 1 | 31.7 | 23.5 |
| Embodiment 2 | 30.2 | 22.2 |
| Comparative | 32.2 | 25.6 |
| Embodiment | | |

As shown in Table 1, it can be ascertained that as in Embodiments 1 and 2, in case that the conductive member 170 is disposed on the side surface of the display panel PN, the conductive member 170 serves as a buffer, such that the maximum main stress is reduced, in comparison with the display device of Comparative Embodiment. In particular, it can be ascertained that the tendency to reduce the maximum main stress is more distinctive as the modulus of the conductive member 170 decreases, as in Embodiment 2. Therefore, according to the display device 100 of Embodiments 1 and 2, the occurrence of cracks in the display panel PN at the edge of the through-hole TH may be reduced as the maximum main stress accumulating on the edge of the through-hole TH decreases in comparison with the display device of Comparative Embodiment. As a result, the reliability of the display device 100 may be improved.

The exemplary embodiments of the present disclosure can also be described as follows:

According to an aspect of the present disclosure, a display device includes a display panel comprising a display area, an optical area disposed in the display area and including a through-hole, and a non-display area configured to surround the display area, a cover member disposed on a top surface of the display panel, a support member disposed on a rear surface of the display panel, a metal plate disposed on a rear surface of the support member, a frame comprising a lower frame disposed on a rear surface of the metal plate, and a lateral frame disposed to surround side surfaces of the display panel, the support member, and the metal plate, a molding member disposed between the display panel, the cover member, the support member, the metal plate, and the frame, and a conductive member disposed between the molding member and the side surface of the display panel, the side surface of the support member, and the side surface of the metal plate at one side of the display panel adjacent to the optical area.

The conductive member may have a modulus of 200 MPa or lower.

The display device may further include a first light-blocking member configured to cover an edge of a rear surface of the cover member exposed by the through-hole and cover an inner surface of the through-hole.

The first light-blocking member may include a conductive material.

The first light-blocking member may include a non-conductive material.

The display device may further include a second light-blocking member configured to cover a part of the edge of the rear surface of the cover member exposed by the through-hole and cover a part of the inner surface of the through-hole, the first light-blocking member may cover a part of the inner surface of the through-hole, and the second light-blocking member may cover the remaining part of the inner surface of the through-hole.

The second light-blocking member may include a conductive material.

The second light-blocking member may have a dot shape, a partially annular sector shape, or a partially annular shape.

The molding member may include curable resin.

The display panel may be bent in a bending area extending and bent from one side of the non-display area at the other side of the display panel opposite to one side of the display panel adjacent to the optical area.

The display device may further include an electronic optical device disposed to overlap the optical area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display panel comprising a display area, an optical area disposed in the display area and including a through-hole, and a non-display area configured to surround the display area;
a cover member disposed on a top surface of the display panel;
a support member disposed on a rear surface of the display panel;
a metal plate disposed on a rear surface of the support member;
a frame comprising a lower frame disposed on a rear surface of the metal plate, and a lateral frame disposed to surround side surfaces of the display panel, the support member, and the metal plate;
a molding member disposed between the display panel, the cover member, the support member, the metal plate, and the frame; and
a conductive member disposed between the molding member and the side surface of the display panel, the side surface of the support member, and the side surface of the metal plate at one side of the display panel adjacent to the optical area.

2. The display device of claim 1, wherein the conductive member has a modulus of 200 MPa or lower.

3. The display device of claim 1, further comprising:
a first light-blocking member configured to cover an edge of a rear surface of the cover member exposed by the through-hole and cover an inner surface of the through-hole.

4. The display device of claim 3, wherein the first light-blocking member includes a conductive material.

5. The display device of claim 3, wherein the first light-blocking member includes a non-conductive material.

6. The display device of claim 5, further comprising:
a second light-blocking member configured to cover a part of the edge of the rear surface of the cover member exposed by the through-hole and cover a part of the inner surface of the through-hole,
wherein the first light-blocking member covers a part of the inner surface of the through-hole, and
wherein the second light-blocking member covers the remaining part of the inner surface of the through-hole.

7. The display device of claim 6, wherein the second light-blocking member includes a conductive material.

8. The display device of claim 6, wherein the second light-blocking member has a dot shape, a partially annular sector shape, or a partially annular shape.

9. The display device of claim 1, wherein the molding member includes curable resin.

10. The display device of claim 1, wherein the display panel is bent in a bending area extending and bent from one side of the non-display area at the other side of the display panel opposite to one side of the display panel adjacent to the optical area.

11. The display device of claim 1, further comprising:
an electronic optical device disposed to overlap the optical area.
